(19) United States
(12) Patent Application Publication
(10) Pub. No.: US 2016/0055965 A1
(43) Pub. Date: Feb. 25, 2016

(54) Stationary Induction Electric Machine

(71) Applicant: HITACHI, LTD., Tokyo (JP)

(72) Inventors: Hideyuki MIYAHARA, Tokyo (JP); Akira YAMAGISHI, Tokyo (JP); Kenji OKUDA, Tokyo (JP); Toshiaki TANAKA, Tokyo (JP)

(21) Appl. No.: 14/780,626

(22) PCT Filed: Mar. 7, 2014
(86) PCT No.: PCT/JP2014/055897

§ 371 Date: Sep. 28, 2015

(30) Foreign Application Priority Data
Apr. 26, 2013 (JP) 2013-093182

(51) Int. Cl. H01F 27/40; H01F 27/24; H01F 27/02; H01F 27/28

(52) U.S. Cl. CPC H01F 27/402; H01F 27/2823; H01F 27/24; H01F 27/02; H01F 2027/406

(57) ABSTRACT

A stationary induction electric machine which makes it possible to detect partial discharge in the stationary induction electric machine with favorable sensitivity and easily retrofit an electromagnetic wave detection sensor to the already installed stationary induction electric machine is provided. The stationary induction electric machine has in a tank a core including a plurality of core legs and a winding wound around the core legs. A polymer bushing 6 is secured on the upper face of the tank through a support fitting 18. The polymer bushing 6 is provided with an electromagnetic wave detection sensor 11, which is placed in a position where the support fitting 18 is avoided.

### TECHNICAL FIELD

The present invention relates to stationary induction electric machines such as transformers and reactors and in particular to a stationary induction electric machine using a polymer bushing.

### BACKGROUND ART

It is a common practice for diagnosing the soundness of electrical machinery and apparatus to detect the presence of partial discharge occurring in a winding of a stationary induction electric machine such as a transformer and a reactor. One of the methods for detecting partial discharge is to detect electromagnetic waves in the UHF (Ultra High Frequency) band radiated from a place of the occurrence of partial discharge with an electromagnetic wave detection sensor or antenna.

Since this electromagnetic wave does not penetrate a metal conductor but is reflected, the electromagnetic wave cannot penetrate a metal tank covering almost all the part of a stationary induction electric machine. For bushings, generally, porcelain insulator-type oil-filled capacitor bushings are used. The interior of such a bushing is sealed with a number of the laminated layers of metal foil of a capacitor core and electromagnetic waves can hardly penetrate the interior.

Consequently, a detection sensor for electromagnetic waves is often installed in the tank beforehand when a stationary induction electric machine is fabricated. Or, the tank is beforehand provided with an insulator observation window and a detection sensor is installed out of the window. However, it is not easy to newly install a detection sensor in a tank in an existing transformer already used in the field. This requires large-scale electrical work, such as stopping the operation of the stationary induction electric machine, pulling out an insulating medium, and modifying the tank.

To solve the above problem, Patent Document 1 discloses an invention in which a transformer tank and a sensor housing container are connected with each other through a butterfly valve.

Specifically, the invention is configured as described below. A partial discharge detection sensor made, up of a signal detecting unit and a sensor support unit is attached to the tip of a pipe-like sensor insertion rod made of metal. A signal cable is installed in the sensor insertion rod and the signal cable is connected to an external terminal. The partial discharge detection sensor provided at one end of the sensor insertion rod is installed in the sensor housing container; and the other end of the sensor insertion rod is pulled out to the outside through an opening formed in the sensor housing container and is slidably supported by a rod support cylinder. Thus the partial discharge detection sensor is configured to be able to be moved between the transformer tank and the sensor housing container.

### CITATION LIST

### Patent Document

Patent Document 1: Japanese Patent Application Laid-Open No. 2010-73984

### SUMMARY OF THE INVENTION

### Technical Problem to be solved by the Invention

In the case of the invention described in Patent Document 1, when an electromagnetic wave detection sensor is retrofitted to an existing stationary induction electric machine, a drain valve of the existing stationary induction electric machine or a valve in a cooler pipe is utilized. Therefore, the position of the electromagnetic wave detection sensor is limited to the positions of these valves. In many cases, these valves are positioned on the side of the stationary induction electric machine tank. It is unknown in which winding of the stationary induction electric machine partial discharge will occur. When the place of occurrence of partial discharge is located far away from the electromagnetic wave detection sensor or on the back side with the core in-between, a problem results. While an electromagnetic wave is repeatedly reflected and propagated, electromagnetic wave signals are attenuated and the detection sensitivity of the electromagnetic wave detection sensor can be degraded.

Consequently, it is an object of the present invention to provide a stationary induction electric machine which makes it possible to detect partial discharge in the stationary induction, electric machine with favorable sensitivity and to easily retrofit an electromagnetic wave detection sensor to the already installed stationary induction electric machine.

### Solution to Problem

To solve the above problem, the present invention provides a stationary induction electric machine having in a tank a core having a plurality of core legs and windings wound around the core legs, characterized in that a polymer bushing is secured on the upper face of the tank through a support fitting and the polymer bushing includes an electromagnetic wave detection sensor, and the electromagnetic wave detection sensor is placed in a position where the support fitting is avoided.

### Advantageous Effects of the Invention

According to the present invention, it is possible to retrofit an electromagnetic wave detection sensor even to an existing stationary induction electric machine and detect partial discharge with favorable sensitivity.

### BRIEF DESCRIPTION OF THE DRAWINGS

FIG. 1 is a schematic diagram illustrating an example of the overall configuration of a stationary induction electric machine of the present invention;

FIG. 2 is a partially cut sectional view showing a joining area between a polymer bushing and the tank in FIG. 1;

FIG. 3 is a drawing illustrating an example of an electromagnetic wave shield; and

FIG. 4 is a drawing illustrating another example of the electromagnetic wave shield.

### DESCRIPTION OF THE EMBODIMENTS

Hereinafter, a description will be given to an embodiment in which the present invention is preferably exploited with reference to the drawings. Below is just an example and is not meant to limit the embodiments of the present invention.

### First embodiment

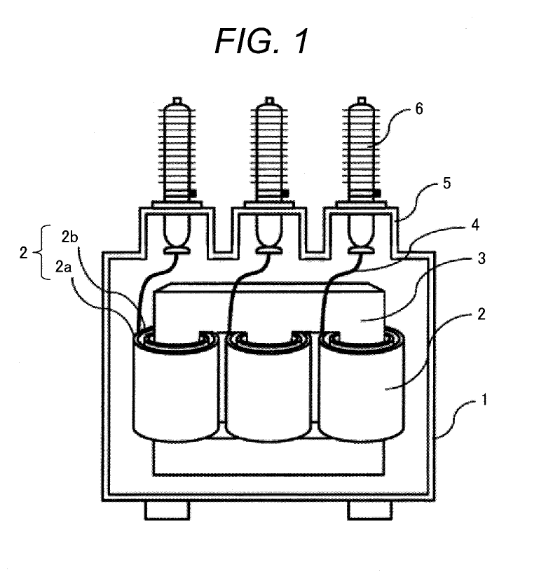

As illustrated in FIG. 1, a core 3, a winding 2 wound on the core 3, and a lead wire 4 connected to the winding 2 are housed in a tank 1 made of metal. A polymer bushing 6 is installed over the upper face of the tank 1 with a bushing pocket 5 in-between.

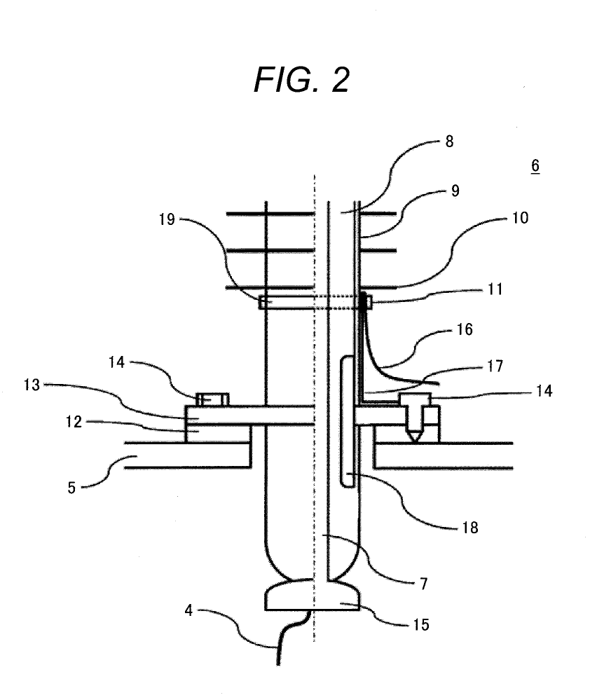

As illustrated in FIG. 2, the polymer bushing 6 is configured by a central conductor 7, a solid insulator 8, a housing 9, a fin 10, a metal flange 13, a support fitting 18, and a bushing lower terminal 15. The central conductor 7 is electrically insulated by the solid insulator 8; and the bushing lower terminal 15 provided on the central conductor 7 is electrically connected to a winding 2 through a lead wire 4.

The surface of the solid insulator 8 located above the metal flange 13 is covered with the housing 9; and the housing 9 has a plurality of fins 10. The support fitting 18 is molded in the solid insulator 8 and plays a role as a reinforcing fitting for supporting the inverted polymer bushing 6; and the support fitting 18 is electrically connected with the metal flange 13 at an identical potential (ground potential).

The polymer bushing 6 is secured on a bushing mounting seat 12 welded to the bushing pocket 5 with a fixing bolt 14 through the metal flange 13 coupled with the support fitting 18 and is thereby coupled with the tank 1. That is, the support fitting 18 is placed on the inner circumference side of the polymer bushing 6.

The polymer bushing 6 is provided with an electromagnetic wave detection sensor 11 on the surface of the housing 9, that is, on the outer circumference side of the polymer bushing 6. The electromagnetic wave detection sensor 11 is secured with a sensor fixture 19 of insulator such as a glass tape and a measurement cable 16 is connected to the sensor. The outer surface of the electromagnetic wave detection sensor 11 is connected between the metal flange and the fixing bolt 14 through a ground wire 17 and grounded.

The electromagnetic wave detection sensor 11 is mounted in a position where the support fitting 18 is avoided. The electromagnetic wave detection sensor 11 is preferably placed above the support fitting 18 and directly under the fin closest to the support fitting 18.

Hereinafter, a description will be given to partial discharge monitoring in the stationary induction electric machine in this embodiment with reference to FIGS. 1 and 2. An electromagnetic wave radiated by partial discharge that occurred in the winding 2 is repeatedly reflected in a conductor constituting the winding 2 and the core 3 and propagated and arrives at the outside of the winding.

Especially, an electromagnetic wave radiated from the interior of the winding 2 in the axial direction of the winding 2 is propagated by way of the insulative separation space between the primary winding 2a and the secondary winding 2b and between the core 3 and the secondary winding 2b, and for this reason, the electromagnetic wave relatively readily arrives at the outside of the winding 2 as compared with propagation in the radial direction of the winding 2.

The electromagnetic wave that has arrived at the outside of the winding arrives at the polymer bushing 6 located immediately above the winding 2. The electromagnetic wave passes through the solid insulator 8 portion between the central conductor 7 and the support fitting 18 in the polymer bushing 6 and is detected by the electromagnetic wave detection sensor 11 attached to the housing 9 above the support fitting 18. That is, the electromagnetic wave does not penetrate the support fitting 18; therefore, the electromagnetic wave penetrates from the upper end side of the support fitting 18 to the outside of the polymer bushing 6 and is detected by the electromagnetic wave detection sensor 11.

The electromagnetic wave detected by the electromagnetic wave detection sensor 11 is converted into an electric signal, which is transmitted to observation equipment through a measurement cable 16. Based on a resulting measurement value thereof, any anomaly is diagnosed in the transformer. The signal may be transmitted using a transmitter and there is not any special limitation on the method of signal transmission from the electromagnetic wave detection sensor 11.

It is desirable that the electromagnetic wave detection sensor 11 should be attached on the outer circumference side of the polymer bushing 6 and above the support fitting 18. Since electromagnetic waves that have propagated between the central conductor 7 and the support fitting 18 are concentrated in this position, electromagnetic waves can be detected here with high sensitivity.

Placement of the electromagnetic wave detection sensor 11 directly under the fins 10 makes it possible to prevent contamination of the sensor due to weather or dust. Therefore, it is preferable that the electromagnetic wave detection sensor 11 should be placed above the support fitting 18 and directly under the fins 10.

FIG. 2 illustrates an example in which the electromagnetic wave detection sensor 11 is placed under the lowest fin 10. For example, in cases where the support fitting 18 is long and extended to above the lowest fin 10, the electromagnetic wave detection sensor 11 may be placed under the second lowest fin 10. However, for the reason of insulating performance, it is desirable that the electromagnetic wave detection sensor 11 should be placed in a position as far from the upper end of the polymer bushing 6 as possible.

In case where the electric machine is placed indoor or other like cases, the electromagnetic wave detection sensor 11 need not be placed directly under the fins 10 as long as there is not a possibility of contamination of the electromagnetic wave detection sensor 11. In such cases, it is desirable that the electromagnetic wave detection sensor 11 should be placed directly above the support fitting 18.

The electromagnetic wave detection sensor 11 may be secured on the polymer bushing 6, for example, with the sensor fixture 19 using a tightening ring or may be secured with an adhesive. Alternatively, the electromagnetic wave detection sensor 11 may be secured with a sensor fixture 19 of such a structure that semicircles obtained by dividing a metal ring into two are coupled together by tightening bolts.

In this case, the outer surface of the electromagnetic wave detection sensor 11 may be grounded together with the sensor fixture 19 by connecting the sensor fixture 19 to the metal flange 13 through the ground wire 17. Methods for attaching or grounding the electromagnetic wave detection sensor 11 in the embodiment are not limited to the foregoing.

In the polymer bushing 6, the solid insulator 8 can be made of, for example, epoxy resin and the housing 9 and the fins 10 can be made of, for example, silicone rubber. The embodiment is not limited to these materials or shapes.

FIG. 1 shows a three-phase, three-leg configuration as an example of the configuration of the stationary induction electric machine but the embodiment is not limited to this. The polymer bushing 6 may be coupled with the tank 1 through the bushing pocket 5 as in this embodiment or may be coupled directly to the tank 1.

In this embodiment, there is a possibility that the electromagnetic wave detection sensor 11 may detect electromagnetic wave noise in the UHF band from outside the stationary induction electric machine. To cope with this, it is desirable that the electromagnetic wave detection sensor 11 should be provided with an electromagnetic wave shield 21.

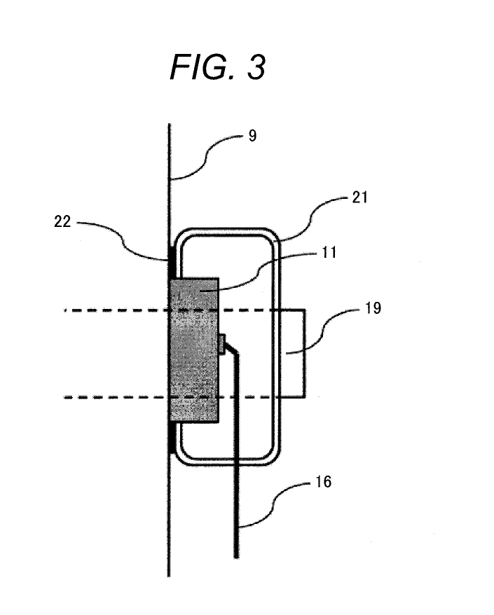

The electromagnetic wave shield 21 can be embodied as shown in FIG. 3, for example, by; bringing the electromagnetic wave detection sensor 11 into contact with the surface of the housing 9; covering the electromagnetic wave detection sensor 11 with the electromagnetic wave shield 21 having packing 22 on the contact surface with the housing 9; securing the electromagnetic wave detection sensor 11 by welding and coupling the sensor with the electromagnetic wave shield 21; tightening the electromagnetic wave shield 21 with the sensor fixture 19 to seal the electromagnetic wave detection sensor 11; and securing the electromagnetic wave shield 21 on the polymer bushing 6.

With the configuration in FIG. 3, the electromagnetic wave detection sensor 11 is sealed with the electromagnetic wave shield 21. This makes it possible to prevent the ingress of rainwater and thus prevent deterioration of the electromagnetic wave detection sensor 11 due to weather and dust without placing the sensor directly under the fins 10. It is desirable that the electromagnetic wave shield 21 should be so shaped that the corners are rounded with electric field relaxation taken into account.

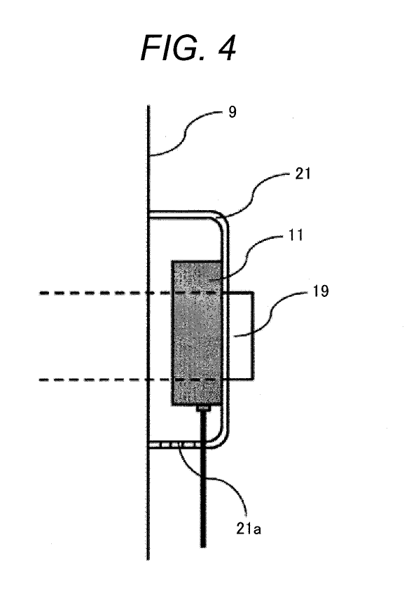

As illustrated in FIG. 4 as an example, the electromagnetic wave shield 21 can also be embodied as described below by covering the electromagnetic detection sensor 11 with the electromagnetic wave shield 21 and sticking it to the electromagnetic wave shield 21 so that the electromagnetic wave detection sensor 11 is not brought into contact with the housing 9, and providing a vent hole 21a of a metal mesh or punching metal in the lower part of the electromagnetic wave shield 21.

In the mode in FIG. 4, even if rainwater moves on the surface of the housing 9 of The polymer bushing 6 and enters from a get between the housing 9 and the electromagnetic wave shield 21, the possibility that the rainwater is brought into contact with the electromagnetic wave detection sensor 11 is reduced and the rainwater is drained from the vent hole in the lower part of the electromagnetic wave shield 21. This makes it possible to prevent deterioration of the electromagnetic wave detection sensor 11 due to weather and dust. Since the packing 22 is not provided, the structure in FIG. 4 is simple as compared with the configuration in FIG. 3.

In the stationary induction electric machine of the present invention, as described up to this point, an electromagnetic wave can be detected on the upper side of a winding 2 in the axial direction where the electromagnetic wave of partial discharge occurring in the winding 2 is readily propagated. Therefore, the electromagnetic wave can be detected before the electromagnetic wave is not attenuated so much by propagation and the detection sensitivity can be enhanced. Furthermore, since the electromagnetic wave detection sensor 11 is attached outside the stationary induction electric machine, the electromagnetic wave detection sensor 11 can also be attached to the already installed stationary induction electric machine.

### REFERENCE SIGNS LIST

1 . . . tank
2 . . . winding
2a . . . primary winding
2b . . . secondary winding
3 . . . core
4 . . . lead wire
5 . . . bushing pocket
6 . . . polymer bushing
7 . . . central conductor
8 . . . solid insulator
9 . . . housing
10 . . . fin
11 . . . electromagnetic wave detection sensor
12 . . . bushing mounting seat
13 . . . metal flange
15 . . . bushing lower terminal
16 . . . measurement cable
17 . . . ground wire
18 . . . support fitting
19 . . . sensor fixture
21 . . . electromagnetic wave shield
21a . . . vent hole
22 . . . packing

1. A stationary induction electric machine having in a tank a core including a plurality of core legs and a winding wound around the core legs,
characterized in that a polymer bushing is secured on the upper face of the tank through a support fitting,
wherein the polymer bushing includes an electromagnetic wave detection sensor, and
wherein the electromagnetic wave detection sensor is placed in a position where the support fitting is avoided.

2. The stationary induction electric machine according to claim 1,
wherein the support fitting is placed on the inner circumference side of the polymer bushing,
wherein the electromagnetic wave detection sensor is placed on the outer circumference side of the polymer bushing, and
wherein the electromagnetic wave detection sensor is placed above the support fitting.

3. The stationary induction electric machine according to claim 1,
wherein the polymer bushing has a plurality of fins, and
wherein the electromagnetic wave detection sensor is placed directly under any one of the fins.

4. The stationary induction electric machine according to claim 2,
wherein the polymer bushing has a plurality of fins, and
wherein the electromagnetic wave detection sensor is placed directly under any one of the fins.

5. The stationary induction electric machine according to claim 1,
wherein the electromagnetic wave detection sensor is sealed with an electromagnetic wave shield.

6. The stationary induction electric machine apparatus according to claim 2,
wherein the electromagnetic wave detection sensor is sealed with an electromagnetic wave shield.

7. The stationary induction electric machine according to claim 1,
wherein the electromagnetic wave detection sensor is placed not in contact with the polymer bushing in an electromagnetic wave shield, and
wherein a vent hole is provided in the lower face of the electromagnetic wave shield.

8. The stationary induction electric machine according to claim 2,
wherein the electromagnetic wave detection sensor is placed not in contact with the polymer bushing in an electromagnetic wave shield, and
wherein a vent hole is provided in the lower face of the electromagnetic wave shield.
